(19) United States
(12) Patent Application Publication
(10) Pub. No.: US 2025/0040403 A1
(43) Pub. Date: Jan. 30, 2025

(54) DISPLAY DEVICE

(71) Applicant: CARUX TECHNOLOGY PTE. LTD., SINGAPORE (SG)

(72) Inventor: Zih-Lin WANG, Tainan (Tainan Science Park) (TW)

(21) Appl. No.: 18/753,072

(22) Filed: Jun. 25, 2024

(30) Foreign Application Priority Data
Jul. 26, 2023 (CN) 202310927807.9

(51) Int. Cl. H10K 59/80

(52) U.S. Cl. CPC H10K 59/872; H10K 59/879

(57) ABSTRACT

A display device is provided. The display device includes a frame, a display unit, a cover lens and an interlayer. The frame has a supporting surface. The display unit is disposed on the frame and has at least one edge. There is a gap between the edge and the frame. The cover lens is disposed on the display unit and includes a first portion, a second portion and a third portion. The first portion overlaps the display unit. The second portion overlaps the gap. The third portion overlaps the supporting surface of the frame. The interlayer is in contact with the surface of the cover lens facing the frame and at least overlaps the gap.

### CROSS REFERENCE TO RELATED APPLICATIONS

This application claims priority of China Patent Application No. 202310927807.9, filed on Jul. 26, 2023, the entirety of which is incorporated by reference herein.

### BACKGROUND OF THE INVENTION

### Field of the Invention

The present invention relates to a display device, and, in particular, to a display device with an interlayer extending below a cover lens.

### Description of the Related Art

Generally, when a cover lens of a display module is hit by an external force, it is easy to break because there is no support or a gap under it, or there is a problem of flying debris after the break.

### BRIEF SUMMARY OF THE INVENTION

In accordance with one embodiment of the present disclosure, a display device is provided. The display device includes a frame, a display unit, a cover lens and an interlayer. The frame has a supporting surface. The display unit is disposed on the frame and has at least one edge. There is a gap between the edge and the frame. The cover lens is disposed on the display unit and includes a first portion, a second portion and a third portion. The first portion overlaps the display unit. The second portion overlaps the gap. The third portion overlaps the supporting surface of the frame. The interlayer is in contact with the surface of the cover lens facing the frame and at least overlaps the gap.

### BRIEF DESCRIPTION OF THE DRAWINGS

The disclosure can be more fully understood from the following detailed description when read with the accompanying figures. It is worth noting that in accordance with standard practice in the industry, various features are not drawn to scale. In fact, the dimensions of the various features may be arbitrarily increased or reduced for clarity of discussion.

FIG. 1 shows a top view of a display device in accordance with one embodiment of the present disclosure;

FIG. 2A shows a cross-sectional view of a display device in accordance with one embodiment of the present disclosure;

FIG. 2B shows a cross-sectional view of a display device in accordance with one embodiment of the present disclosure;

FIG. 3A shows a cross-sectional view of a local area in a display device in accordance with one embodiment of the present disclosure;

FIG. 3B shows a cross-sectional view of a local area in a display device in accordance with one embodiment of the present disclosure;

FIG. 3C shows a cross-sectional view of a local area in a display device in accordance with one embodiment of the present disclosure;

FIG. 4A shows a cross-sectional view of a local area in a display device in accordance with one embodiment of the present disclosure;

FIG. 4B shows a cross-sectional view of a local area in a display device in accordance with one embodiment of the present disclosure; and

FIG. 5 shows a cross-sectional view of a local area in a display device in accordance with one embodiment of the present disclosure.

### DETAILED DESCRIPTION OF THE INVENTION

Various embodiments or examples are provided in the following description to implement different features of the present disclosure. The elements and arrangement described in the following specific examples are merely provided for introducing the present disclosure and serve as examples without limiting the scope of the present disclosure. For example, when a first component is referred to as “on a second component”, it may directly contact the second component, or there may be other components in between, and the first component and the second component do not come in direct contact with one another.

It should be understood that additional operations may be provided before, during, and/or after the described method. In accordance with some embodiments, some of the stages (or steps) described below may be replaced or omitted.

In this specification, spatial terms may be used, such as “below”, “lower”, “above”, “higher” and similar terms, for briefly describing the relationship between an element relative to another element in the figures. Besides the directions illustrated in the figures, the devices may be used or operated in different directions. When the device is turned to different directions (such as rotated 45 degrees or other directions), the spatially related adjectives used in it will also be interpreted according to the turned position. In some embodiments of the present disclosure, terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

It should be understood that, although the terms “first”, “second”, “third”, etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer, portion or section. Thus, a first element, component, region, layer, portion or section discussed below could be termed a second element, component, region, layer, portion or section without departing from the teachings of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

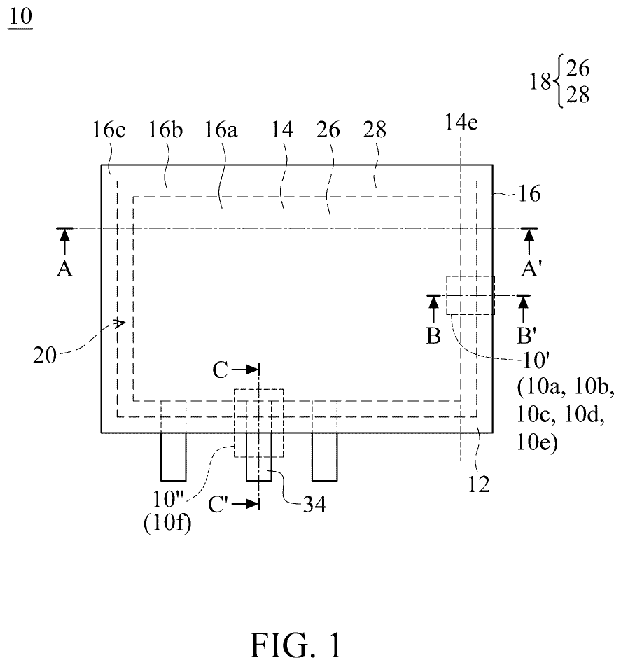

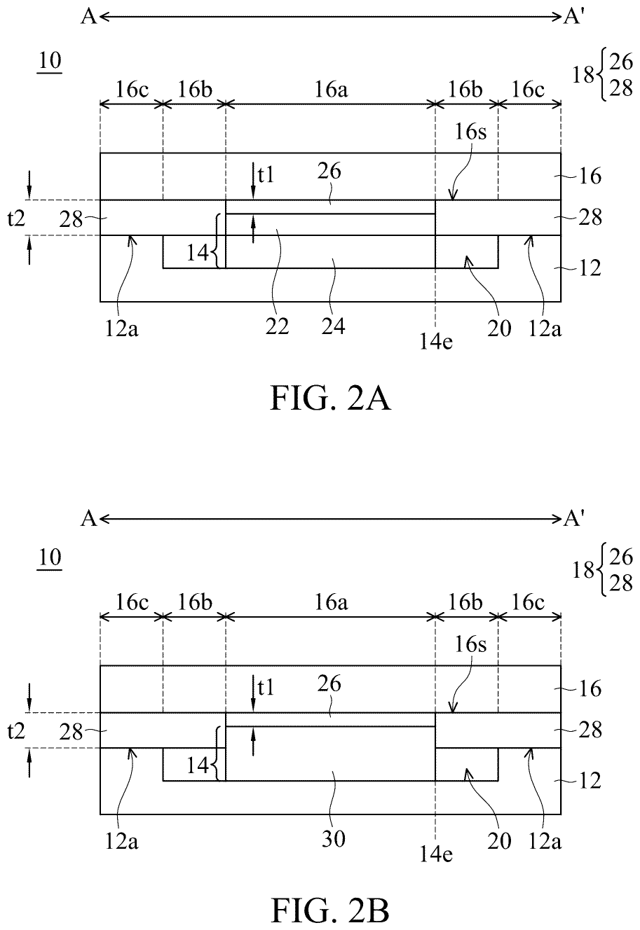

Referring to FIGS. 1 and 2A, in accordance with one embodiment of the present disclosure, a display device 10 is provided. FIG. 1 shows a top view of the display device 10. FIG. 2A shows a cross-sectional view of the display device 10 obtained along the cross-sectional line A-A′ in FIG. 1.

As shown in FIGS. 1 and 2A, the display device 10 includes a frame 12, a display unit 14, a cover lens 16 and an interlayer 18. The display unit 14 is disposed on the frame 12 and has at least one edge 14e. There is a gap 20 between the edge 14e of the display unit 14 and the frame 12. The cover lens 16 is disposed on the display unit 14 and includes a first portion 16a, a second portion 16b and a third portion 16c. The first portion 16a of the cover lens 16 overlaps the display unit 14. The second portion 16b of the cover lens 16 overlaps the gap 20. The third portion 16c of the cover lens 16 overlaps the supporting surface 12a of the frame 12. The interlayer 18 is in contact with the surface 16s of the cover lens 16 facing the frame 12 and at least overlaps the gap 20.

In accordance with some embodiments, the frame 12 may include a rigid structure, such as a housing or a support structure, but the present disclosure is not limited thereto, and other suitable rigid structures are also applicable to the present disclosure. In accordance with some embodiments, the material of the frame 12 may include hard materials, such as metal or plastic, but the present disclosure is not limited thereto, and other suitable hard materials are also applicable to the present disclosure.

In accordance with some embodiments, the display unit 14 may include a non-self-luminous display unit. In accordance with some embodiments, when the display unit 14 is a non-self-luminous display unit, the display unit 14 may include a liquid-crystal (LC) display panel 22 and a backlight module 24, as shown in FIG. 2A. In accordance with some embodiments, the liquid-crystal (LC) display panel 22 may include, for example, any combination of a liquid-crystal layer, upper and lower substrates, polarizers, driving circuits, color-conversion layers (such as color filters, quantum dots or combinations thereof) or compensation films, but the present disclosure is not limited thereto, and other suitable optical components and/or electronic components are also applicable to the present disclosure. In accordance with some embodiments, the backlight module 24 may include, for example, any combination of reflectors, light sources, light-guide plates, upper and lower diffusion films, prism sheets, or brightness enhancement films, but the present disclosure is not limited thereto, and other suitable optical components are also applicable to the present disclosure. In accordance with some embodiments, the lighting mode of the backlight module 24 may include, for example, a global-dimming mode or a local-dimming mode. In accordance with some embodiments, the backlight module 24 may be, for example, an edge-type backlight module or a direct-type backlight module.

In accordance with some embodiments, the material of the cover lens 16 may include glass or plastic, but the present disclosure is not limited thereto.

In accordance with some embodiments, the interlayer 18 may be composed of multiple components. For example, the interlayer 18 may be composed of a first interlayer 26 and a second interlayer 28, as shown in FIG. 2A, but the number of interlayers is not limited thereto. In accordance with some embodiments, the thickness t1 of the first interlayer 26 and the thickness t2 of the second interlayer 28 may be the same or different. For example, the thickness t1 of the first interlayer 26 may be smaller than the thickness t2 of the second interlayer 28. In accordance with some embodiments, the thickness t1 of the first interlayer 26 and the thickness t2 of the second interlayer 28 are greater than 0 and less than or equal to 5 mm, but the present disclosure is not limited thereto. In accordance with some embodiments, the materials of the first interlayer 26 and the second interlayer 28 may be the same or different. In accordance with some embodiments, the elastic coefficient of the first interlayer 26 and the second interlayer 28 is between 0.1 Mpa and 2 Gpa (0.1 Mpa≤the elastic coefficient of the interlayer≤2 Gpa), but the present disclosure is not limited thereto. In accordance with some embodiments, the interlayer 18 may be, for example, a joint object. The material of the interlayer 18 may include, for example, solid optical clear adhesive (OCA), liquid optical clear resin (OCR), pressure sensitive adhesive (PSA), or foam glue, etc., but the present disclosure is not limited thereto, and other suitable various glues, single-sided tapes or double-sided tapes are also applicable to the present disclosure. As shown in FIG. 2A, the interlayer 18 may be disposed between the cover lens 16 and at least one of the display unit 14 and the supporting surface 12a of the frame 12. For example, the first interlayer 26 may be disposed between the cover lens 16 and the display unit 14, and the second interlayer 28 may be disposed between the cover lens 16 and the supporting surface 12a of the frame 12. The interlayer 18 may be in contact with at least one of the display unit 14 and the supporting surface 12a of the frame 12. For example, the first interlayer 26 may be in contact with the display unit 14, and the second interlayer 28 may be in contact with the supporting surface 12a of the frame 12.

In accordance with FIG. 2A, more specifically, the first portion 16a of the cover lens 16 overlaps the first interlayer 26 and the display unit 14, and the first portion 16a of the cover lens 16 is further in contact with the first interlayer 26. The second portion 16b of the cover lens 16 overlaps and contacts the second interlayer 28 extending across the gap 20. The third portion 16c of the cover lens 16 overlaps the second interlayer 28 and the supporting surface 12a of the frame 12, and the third portion 16c of the cover lens 16 is further in contact with the second interlayer 28. That is, in the display device 10, any position corresponding to the gap 20 under the cover lens 16 is at least partially provided with a support (for example, the first interlayer 26 or the second interlayer 28) to contact and support the cover lens 16. The structural design enhances the structural strength of the cover lens 16. When it is hit by an external force, it will not easily cause structural rupture or slow down the scattering of broken fragments.

Referring to FIG. 2B, in accordance with one embodiment of the present disclosure, a display device 10 is provided. FIG. 2B shows a cross-sectional view of the display device 10.

In FIG. 2B, the parts similar to those disclosed in FIG. 2A will not be repeated here. In the embodiment shown in FIG. 2B, the display unit 14 may include a self-luminous display unit 30. In accordance with some embodiments, the self-luminous display unit 30 may include a light-emitting diode (LED) display panel or an organic light-emitting diode (OLED) display panel.

In accordance with some embodiments, the light-emitting diode (LED) display panel may include submillimeter light-emitting diodes (mini LEDs), micro light-emitting diodes (micro LEDs), or quantum dot light-emitting diodes (quantum dot LEDs, QLED/QDLEDs), etc., but the present disclosure is not limited thereto.

In accordance with some embodiments, the organic light-emitting diode (OLED) display panel may include active organic light-emitting diodes (AMOLEDs), passive organic light-emitting diodes (PMOLEDs), transparent OLEDs, top-emitting OLEDs, foldable OLEDs, or white-light OLEDs, etc., but the present disclosure is not limited thereto.

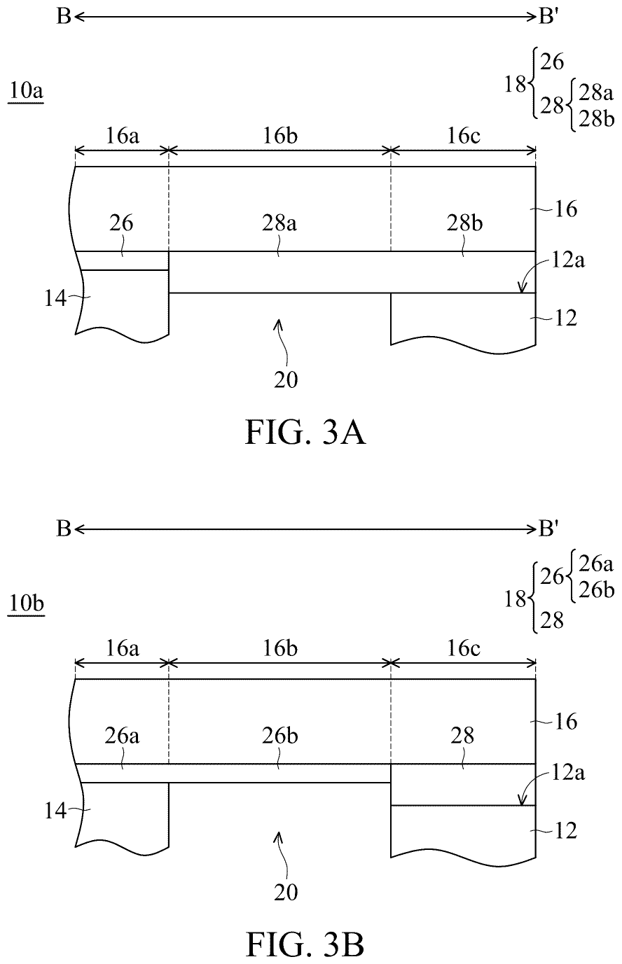

Referring to FIG. 3A, in accordance with one embodiment of the present disclosure, a structure 10a in a local area 10′ (as shown in FIG. 1) in a display device 10 is provided. FIG. 3A shows a cross-sectional view of the structure 10a in the local area 10′ in the display device 10. FIG. 3A is the cross-sectional view of the display device 10 obtained along the cross-sectional line B-B′ in FIG. 1.

As shown in FIG. 3A, in the structure 10a, the interlayer 18 may be composed of a first interlayer 26 and a second interlayer 28, and the second interlayer 28 includes a first portion 28a and a second portion 28b. The thickness and material of the first interlayer 26 and the second interlayer 28 are similar to those disclosed in FIG. 2A, and will not be repeated here. In FIG. 3A, the first interlayer 26 may be disposed between the cover lens 16 and the display unit 14. The second portion 28b of the second interlayer 28 may be disposed between the cover lens 16 and the supporting surface 12a of the frame 12, but not limited thereto. In addition, the first interlayer 26 may be in contact with the display unit 14. The second portion 28b of the second interlayer 28 may be in contact with the supporting surface 12a of the frame 12, but not limited thereto.

In accordance with FIG. 3A, more specifically, the first portion 16a of the cover lens 16 overlaps and contacts the first interlayer 26 and the display unit 14. The second portion 16b of the cover lens 16 overlaps and contacts the first portion 28a of the second interlayer 28 extending across the gap 20. The third portion 16c of the cover lens 16 overlaps and contacts the second portion 28b of the second interlayer 28 and the supporting surface 12a of the frame 12. In addition, the first portion 28a of the second interlayer 28 may, for example, be in contact with the first interlayer 26.

Referring to FIG. 3B, in accordance with one embodiment of the present disclosure, a structure 10b in a local area 10′ (as shown in FIG. 1) in a display device 10 is provided. FIG. 3B shows a cross-sectional view of the structure 10b in the local area 10′ in the display device 10. FIG. 3B is the cross-sectional view of the display device 10 obtained along the cross-sectional line B-B′ in FIG. 1.

As shown in FIG. 3B, in the structure 10b, the interlayer 18 may be composed of a first interlayer 26 and a second interlayer 28, and the first interlayer 26 includes a first portion 26a and a second portion 26b. The thickness and material of the first interlayer 26 and the second interlayer 28 are similar to those disclosed in FIG. 2A, and will not be repeated here. In FIG. 3B, the first portion 26a of the first interlayer 26 may be disposed between the cover lens 16 and the display unit 14. The second interlayer 28 may be disposed between the cover lens 16 and the supporting surface 12a of the frame 12, but not limited thereto. In addition, the first portion 26a of the first interlayer 26 may be in contact with the display unit 14. The second interlayer 28 may be in contact with the supporting surface 12a of the frame 12, but not limited thereto.

In accordance with FIG. 3B, more specifically, the first portion 16a of the cover lens 16 overlaps and contacts the first portion 26a of the first interlayer 26 and the display unit 14. The second portion 16b of the cover lens 16 overlaps and contacts the second portion 26b of the first interlayer 26 extending across the gap 20. The third portion 16c of the cover lens 16 overlaps and contacts the second interlayer 28 and the supporting surface 12a of the frame 12. In addition, the second portion 26b of the first interlayer 26 may, for example, be in contact with the second interlayer 28.

Referring to FIG. 3C, in accordance with one embodiment of the present disclosure, a structure 10c in a local area 10′ (as shown in FIG. 1) in a display device 10 is provided. FIG. 3C shows a cross-sectional view of the structure 10c in the local area 10′ in the display device 10. FIG. 3C is the cross-sectional view of the display device 10 obtained along the cross-sectional line B-B′ in FIG. 1.

As shown in FIG. 3C, in the structure 10c, the interlayer 18 may be composed of a first interlayer 26 and a second interlayer 28. The first interlayer 26 includes a first portion 26a and a second portion 26b. The second interlayer 28 includes a first portion 28a and a second portion 28b. The thickness and material of the first interlayer 26 and the second interlayer 28 are similar to those disclosed in FIG. 2A, and will not be repeated here. In FIG. 3C, the first portion 26a of the first interlayer 26 may be disposed between the cover lens 16 and the display unit 14. The second portion 28b of the second interlayer 28 may be disposed between the cover lens 16 and the supporting surface 12a of the frame 12, but not limited thereto. In addition, the first portion 26a of the first interlayer 26 may be in contact with the display unit 14. The second portion 28b of the second interlayer 28 may be in contact with the supporting surface 12a of the frame 12, but not limited thereto.

In accordance with FIG. 3C, more specifically, the first portion 16a of the cover lens 16 overlaps and contacts the first portion 26a of the first interlayer 26 and the display unit 14. The second portion 16b of the cover lens 16 overlaps and contacts the second portion 26b of the first interlayer 26 and the first portion 28a of the second interlayer 28 which extend across the gap 20. The third portion 16c of the cover lens 16 overlaps and contacts the second portion 28b of the second interlayer 28 and the supporting surface 12a of the frame 12. In addition, the second portion 26b of the first interlayer 26 may, for example, be in contact with the first portion 28a of the second interlayer 28. In the structures (10a, 10b and 10c), any position corresponding to the gap 20 under the cover lens 16 is at least partially provided with a support (for example, the first interlayer 26 or the second interlayer 28) to contact and support the cover lens 16. When it is hit by an external force, it will not easily cause structural rupture or slow down the scattering of broken fragments.

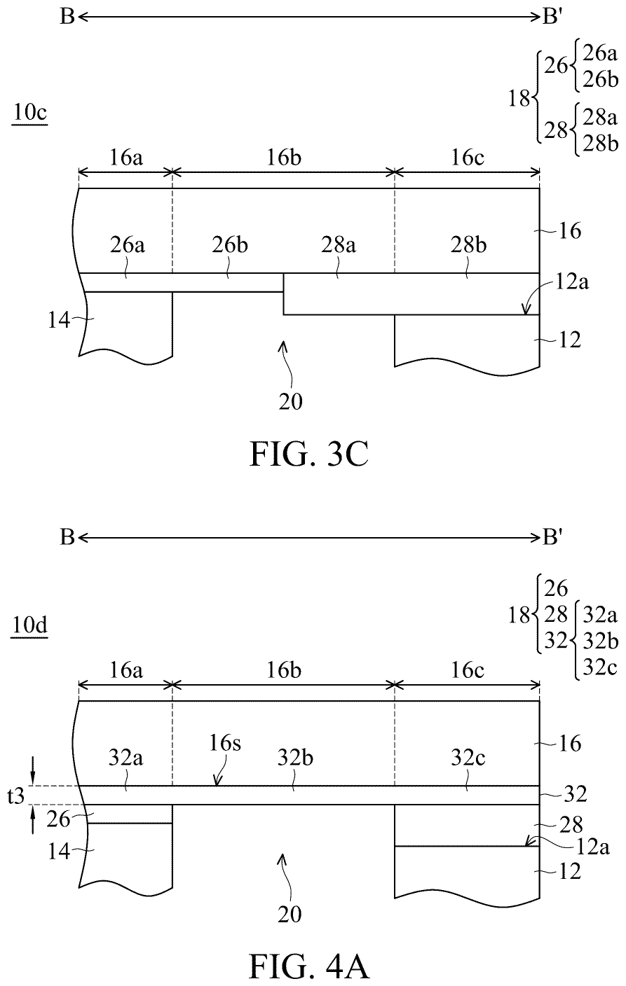

Referring to FIG. 4A, in accordance with one embodiment of the present disclosure, a structure 10d in a local area 10′ (as shown in FIG. 1) in a display device 10 is provided. FIG. 4A shows a cross-sectional view of the structure 10d in the local area 10′ in the display device 10. FIG. 4A is the cross-sectional view of the display device 10 obtained along the cross-sectional line B-B′ in FIG. 1.

As shown in FIG. 4A, in the structure 10d, the interlayer 18 may be composed of a first interlayer 26, a second interlayer 28, and a third interlayer 32. The third interlayer 32 includes a first portion 32a, a second portion 32b, and a third portion 32c. The third interlayer 32 is disposed on the surface 16s of the cover lens 16 facing the frame 12, and is located between the cover lens 16 and the first interlayer 26 and the second interlayer 28. In accordance with some embodiments, the thickness t3 of the third interlayer 32 is greater than 0 and less than or equal to 5 mm, but the present disclosure is not limited thereto. In accordance with some embodiments, the materials of the first interlayer 26, the second interlayer 28, and the third interlayer 32 may be the same or different. In accordance with some embodiments, the elastic coefficient of the third interlayer 32 is between 0.1 Mpa and 2 Gpa (0.1 Mpa≤the elastic coefficient of the interlayer≤2 Gpa), but the present disclosure is not limited thereto. The thickness and material of the first interlayer 26, the second interlayer 28 and the third interlayer 32 are similar to those disclosed in FIG. 2A, and will not be repeated here. In FIG. 4A, the first portion 32a of the third interlayer 32 and the first interlayer 26 may be disposed between the cover lens 16 and the display unit 14. The third portion 32c of the third interlayer 32 and the second interlayer 28 may be disposed between the cover lens 16 and the supporting surface 12a of the frame 12. Furthermore, the first interlayer 26 may be in contact with the display unit 14. The second interlayer 28 may be in contact with the supporting surface 12a of the frame 12, but not limited thereto.

In accordance with FIG. 4A, more specifically, the first portion 16a of the cover lens 16 overlaps the first portion 32a of the third interlayer 32, the first interlayer 26, and the display unit 14. The first portion 16a of the cover lens 16 is further in contact with the first portion 32a of the third interlayer 32. The second portion 16b of the cover lens 16 overlaps and contacts the second portion 32b of the third interlayer 32 located in the gap 20. The third portion 16c of the cover lens 16 overlaps the third portion 32c of the third interlayer 32, the second interlayer 28, and the supporting surface 12a of the frame 12. The third portion 16c of the cover lens 16 is further in contact with the third portion 32c of the third interlayer 32. That is, in the structure 10d, any position corresponding to the gap 20 under the cover lens 16 is at least partially provided with a support (for example, the third interlayer 32) to contact and support the cover lens 16.

Referring to FIG. 4B, in accordance with one embodiment of the present disclosure, a structure 10e in a local area 10′ (as shown in FIG. 1) in a display device 10 is provided. FIG. 4B shows a cross-sectional view of the structure 10e in the local area 10′ in the display device 10. FIG. 4B is the cross-sectional view of the display device 10 obtained along the cross-sectional line B-B′ in FIG. 1.

As shown in FIG. 4B, in the structure 10e, the interlayer 18 may be composed of a first interlayer 26, a second interlayer 28, and a third interlayer 32. The third interlayer 32 is disposed on the surface 16s of the cover lens 16 facing the frame 12, and is located between the first interlayer 26 and the second interlayer 28. The thickness and material of the first interlayer 26, the second interlayer 28 and the third interlayer 32 are similar to those disclosed in FIG. 4A, and will not be repeated here. In FIG. 4B, the first interlayer 26 may be disposed between the cover lens 16 and the display unit 14. The second interlayer 28 may be disposed between the cover lens 16 and the supporting surface 12a of the frame 12, but not limited thereto. In addition, the first interlayer 26 may be in contact with the display unit 14. The second interlayer 28 may be in contact with the supporting surface 12a of the frame 12, but not limited thereto.

In accordance with FIG. 4B, more specifically, the first portion 16a of the cover lens 16 overlaps and contacts the first interlayer 26 and the display unit 14. The second portion 16b of the cover lens 16 overlaps and contacts the third interlayer 32 located in the gap 20. The third portion 16c of the cover lens 16 overlaps and contacts the second interlayer 28 and the supporting surface 12a of the frame 12. That is, in the structure 10e, any position corresponding to the gap 20 under the cover lens 16 is at least partially provided with a support (for example, the first interlayer 26, the second interlayer 28 or the third interlayer 32) to contact and support the cover lens 16.

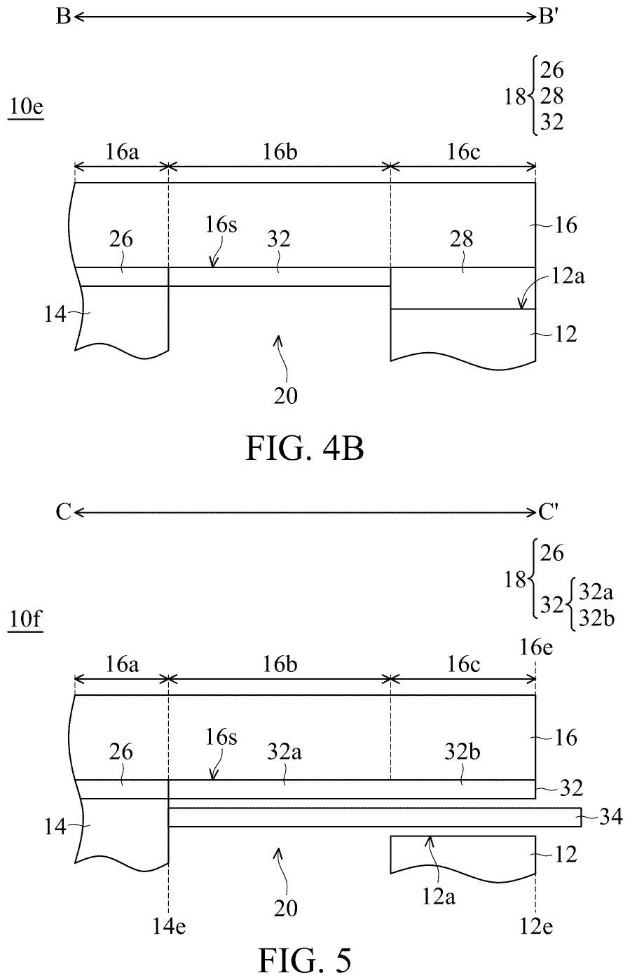

Referring to FIG. 5, in accordance with one embodiment of the present disclosure, a structure 10f in a local area 10″ (as shown in FIG. 1) in a display device 10 is provided. FIG. 5 shows a cross-sectional view of the structure 10f in the local area 10″ in the display device 10. FIG. 5 is the cross-sectional view of the display device 10 obtained along the cross-sectional line C-C′ in FIG. 1.

As shown in FIG. 5, in the structure 10f, the interlayer 18 may be composed of a first interlayer 26 and a third interlayer 32. The third interlayer 32 includes a first portion 32a and a second portion 32b. The third interlayer 32 is disposed on the surface 16s of the cover lens 16 facing the frame 12 and adjacent to the first interlayer 26. The thickness and material of the first interlayer 26 and the third interlayer 32 are similar to those disclosed in FIG. 4A, and will not be repeated here. In FIG. 5, the first interlayer 26 may be disposed between the cover lens 16 and the display unit 14. The second portion 32b of the third interlayer 32 may be disposed between the cover lens 16 and the supporting surface 12a of the frame 12, but not limited thereto. In addition, the first interlayer 26 may be in contact with the display unit 14, but not limited thereto. It should be noted that, in the structure 10f, a circuit board 34 is further provided under the cover lens 16 to electrically connect to the display unit 14. For example, the circuit board 34 may extend from the edge 14e of the display unit 14 towards the edge 16e of the cover lens 16. In accordance with some embodiments, the circuit board 34 may extend beyond the edge 12e of the frame 12, or the portion of the circuit board 34 extending beyond the edge 12e may be further bent down to the back side of the frame 12 (not shown), but not limited thereto. In the structure 10f, the third interlayer 32 overlaps the circuit board 34. The circuit board 34 includes a printed circuit board (PCB), a flexible printed circuit board (FPC), or a chip-on-film (COF) package, but not limited thereto.

In accordance with FIG. 5, more specifically, the first portion 16a of the cover lens 16 overlaps and contacts the first interlayer 26 and the display unit 14. The second portion 16b of the cover lens 16 overlaps and contacts the first portion 32a of the third interlayer 32 located in the gap 20. The third portion 16c of the cover lens 16 overlaps and contacts the second portion 32b of the third interlayer 32 and the supporting surface 12a of the frame 12. That is, in the structure 10f, any position corresponding to the gap 20 under the cover lens 16 is at least partially provided with a support (for example, the first interlayer 26 or the third interlayer 32) to contact and support the cover lens 16. In particular, in the region where the circuit board 34 extends, for example, the third interlayer 32 serves as the main support for the cover lens 16. In accordance with some embodiments, the third interlayer 32 may be at least partially separated from the circuit board 34 (or there is a gap between the third interlayer 32 and the circuit board 34), so as to avoid affecting the wiring area of the circuit board 34 and/or electronic components on the circuit board 34. In accordance with some embodiments, the third interlayer 32 may preferably adopt single-sided tapes or foam glue. In accordance with some embodiments, the third interlayer 32 may be in contact with the circuit board 34.

In the present disclosure, the interlayer that is attached to the cover lens to fill the gap under the cover lens is used to achieve a buffering effect, so that the cover lens is not easy to break when an external force hits it, and at the same time the problem of flying debris can be avoided. In addition, in the wiring area of the circuit board, the same buffering effect can also be achieved by attaching an interlayer. In the present disclosure, the cost can be greatly reduced by using the interlayer attached to the cover lens in the original structure to extend to the gap under the cover lens, or attaching the interlayer to increase the strength of the cover lens. Furthermore, the attached interlayer in the wiring area of the circuit board can preferably adopt single-sided tapes or foam tape, or a gap can be left between the interlayer and the wiring area of the circuit board to reduce the impact of the interlayer on the wiring area of the circuit board.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods or steps. In addition, each claim constitutes an individual embodiment, and the claimed scope of the present disclosure includes the combinations of the claims and embodiments. The scope of protection of present disclosure is subject to the definition of the scope of the appended claims. Any embodiment or claim of the present disclosure does not need to meet all the purposes, advantages, and features disclosed in the present disclosure.

What is claimed is:

1. A display device, comprising:
a frame having a supporting surface;
a display unit disposed on the frame and having at least one edge, wherein there is a gap between the edge and the frame;
a cover lens disposed on the display unit and comprising a first portion, a second portion and a third portion, wherein the first portion overlaps the display unit, the second portion overlaps the gap, and the third portion overlaps the supporting surface of the frame; and
an interlayer in contact with the surface of the cover lens facing the frame and at least overlapping the gap.

2. The display device as claimed in claim 1, wherein the interlayer is disposed between the cover lens and the display unit.

3. The display device as claimed in claim 2, wherein the interlayer overlaps the display unit and is in contact with the first portion.

4. The display device as claimed in claim 2, wherein the interlayer overlaps and contacts the second portion.

5. The display device as claimed in claim 2, wherein the interlayer extends across the gap.

6. The display device as claimed in claim 2, wherein the interlayer is in contact with the display unit.

7. The display device as claimed in claim 1, wherein the interlayer is disposed between the cover lens and the frame.

8. The display device as claimed in claim 7, wherein the interlayer overlaps the supporting surface and is in contact with the third portion.

9. The display device as claimed in claim 7, wherein the interlayer overlaps and contacts the second portion.

10. The display device as claimed in claim 7, wherein the interlayer extends across the gap.

11. The display device as claimed in claim 7, wherein the interlayer is in contact with the frame.

12. The display device as claimed in claim 1, wherein the interlayer is disposed between the cover lens and the display unit and the frame.

13. The electronic device as claimed in claim 12, wherein the interlayer comprises a first interlayer and a second interlayer, the first interlayer overlaps the display unit, and the second interlayer overlaps the supporting surface, wherein the first interlayer has a thickness different from that of the second interlayer.

14. The electronic device as claimed in claim 12, wherein the interlayer is in contact with the first portion, the second portion and the third portion.

15. The electronic device as claimed in claim 12, wherein the first interlayer and the second interlayer extend across the gap.

16. The electronic device as claimed in claim 12, wherein the interlayer is in contact with the display unit and the frame.

17. The electronic device as claimed in claim 12, wherein the interlayer overlaps the first portion, the second portion and the third portion.

18. The display device as claimed in claim 1, further comprising a circuit board electrically connected to the display unit and overlapping the interlayer.

19. The display device as claimed in claim 1, wherein the interlayer has a thickness greater than 0 and less than or equal to 5 mm.

20. The display device as claimed in claim 1, wherein the interlayer has an clastic coefficient between 0.1 Mpa and 2 Gpa.
